(19) United States
(12) Patent Application Publication
(10) Pub. No.: US 2024/0107791 A1
(43) Pub. Date: Mar. 28, 2024

(54) OPTOELECTRONIC DEVICE

(71) Applicant: TCL TECHNOLOGY GROUP CORPORATION, Huizhou (CN)

(72) Inventor: Yixing YANG, Huizhou (CN)

(21) Appl. No.: 18/270,719

(22) PCT Filed: Dec. 27, 2021
(86) PCT No.: PCT/CN2021/141746

§ 371 Date: Jun. 30, 2023

(30) Foreign Application Priority Data
Dec. 31, 2020 (CN) 202011639205.6

(51) Int. Cl. H10K 50/115; C07F 3/06; C09K 11/88; H10K 85/30

(52) U.S. Cl. CPC H10K 50/115; C07F 3/06; C09K 11/883; H10K 85/381; H10K 50/16

(57) ABSTRACT

An optoelectronic device, including an anode, a hole transport layer, a quantum dot light-emitting layer, an electron transport layer, and a cathode stacked in sequence; the quantum dot light-emitting layer includes a quantum dot material with a core-shell structure, and the difference between the valence band top energy level of the shell layer of the quantum dot material and the hole transport material is greater than or equal to 0.5 eV; the electron transport layer includes a zinc oxide nanomaterial, and an amine group/carboxyl ligand having a chain length of 3-8 carbon atoms is bonded to the surface of the zinc oxide nanomaterial.

### CROSS-REFERENCE TO RELATED APPLICATIONS

The present application is the U.S. national phase of International Application No. PCT/CN2021/141746 with an international filing date of Dec. 27, 2021, designating the U.S., now pending, and claims the priority of the Chinese patent application with the application number 202011639205.6 and the invention title “OPTOELECTRONIC DEVICE”, filed in the China Patent Office on Dec. 31, 2020, the entire contents each of which are incorporated herein by reference.

### TECHNICAL FIELD

The present application relates to the field of display technology, and more particularly to an optoelectronic device.

### BACKGROUND

The statements herein merely provide background information related to the present application and do not necessarily constitute prior art. Quantum dot light-emitting display technology (QLED) is a new type of display technology that has emerged rapidly in recent years. Similar to organic light-emitting display (OLED), QLED is an active light-emitting technology, therefore being advantageous in high luminous efficiency, fast response speed, high contrast, wide viewing angle, and other advantages. Due to the excellent material properties of quantum dots in QLED display technology, QLED has performance advantages over OLED in many aspects, for example, the emission of quantum dots is continuously adjustable and the emission width is extremely narrow, which can achieve a wider color gamut and higher purity display; the inorganic material characteristics of quantum dots make QLED have better device stability; the driving voltage of the QLED device is lower than that of OLED, which can achieve higher brightness and reduce energy consumption; meanwhile, the QLED display technology matches with the production process and technology of printing display, which can realize the high-efficiency mass production preparation of large size, low production cost, and rollability. Therefore, the QLED is considered to be one of the preferred technologies for next-generation display screens that are thin, portable, flexible, transparent, and high-performance in the future.

Due to the similarity in the light-emitting principles of QLED and OLED display technology, in the development process of the QLED display technology, many of the device structures of the QLED refer to those in the OLED display technology, except that the organic light-emitting material for the light-emitting layer material is replaced by the quantum dot materials, other functional layer materials, such as the charge injection layer or the charge transport layer, often use existing materials in OLEDs. Moreover, the explanation of device physics in QLED devices, the selection and collocation of energy levels of functional layer materials, etc. also follow the existing theoretical system in OLED. The application of the classical device physics conclusions obtained in the research of OLED devices to the QLED device system has indeed significantly improved the performance of QLED devices, especially the efficiency of the QLED device.

However, the classical ideas and strategies currently formed in OLED cannot effectively improve the service life of the QLED device, and although the efficiency of QLED device can be improved through the classic idea and strategy of the OLED device, it is found that the service life of such kind of high-efficiency QLED device is significantly inferior to similar devices with lower efficiency. Therefore, the existing QLED device structure based on the theoretical system of the OLED device cannot improve both the photoelectric efficiency and the life performance of the QLED device. For the unique device mechanism of the QLED device system, new and more targeted QLED device structures need to be developed.

### SUMMARY

It is one of the objectives of embodiments of the present application to provide an optoelectronic device, which aims to solve the problem that it is difficult in the related art to improve both the optoelectronic efficiency and the life performance of the QLED device.

In order to solve the above technical problems, the technical solutions adopted in the embodiments of the present application are as follows:

An electrical device is provided. The optoelectronic device comprises: an anode, a hole transport layer disposed on the anode, a quantum dot light-emitting layer disposed on the hole transport layer, an electron transport layer disposed on the quantum dot light-emitting layer, and a cathode disposed on the electron transport layer. The quantum dot light-emitting layer comprises a quantum dot material in a core-shell structure. A valence band top energy level difference between an shell layer material of the quantum dot material and a hole transport material in the hole transport layer is greater than or equal to 0.5 eV. The electron transport layer comprises a zinc oxide nanomaterial, and a surface of the zinc oxide nanomaterial is bound with an amine/carboxyl ligand having a chain length of between 3 and 8 carbon atoms.

Advantages of the optoelectronic devices provided by embodiments of the present application are summarized as follows: on the one hand, a valence band top energy level difference between the shell layer material of the quantum dot material and the hole transport material is constructed to be greater than or equal to 0.5 eV, that is, E_{EML-HTL}≥0.5 eV. The hole injection efficiency is reduced by increasing the hole injection barrier, thereby balancing the injection balance of holes and electrons in the light-emitting layer. On the other hand, the zinc oxide nanomaterial having amine/carboxyl ligands with a chain length of between 3 and 8 carbon atoms is bound to the surface of the electron transport layer, and amine group/carboxyl ligands with the chain length of between 3 and 8 carbon atoms are used to replace the hydroxyl ligands on the surface of zinc oxide colloid, which can effectively reduce the content of negatively charged hydroxyl groups on the surface of zinc oxide nanomaterial, and reduce the electronegativity of zinc oxide nanomaterial, thereby reducing the inhibition and hindering of negatively charged hydroxyl groups on the electron transport, and therefore improving the efficiency of electron transfer and injection. In addition, the chain length of amine/carboxyl ligands is between 3 and 8 carbon atoms, the chain length is short, the steric hindrance effect is small, and the distance between ZnO nanoparticles and the electron transfer efficiency of the inter-nanoparticles in the electron transport layer film will not be increased. In this way, the injection rate of holes and electrons in the light-emitting device is balanced, the recombination efficiency of electrons and holes is improved, the charge accumulation caused by unbalanced carrier injection is avoided, and the luminous efficiency and service life of the light-emitting device are improved.

### BRIEF DESCRIPTION OF THE DRAWINGS

In order to more clearly illustrate the technical solutions in the embodiments of the present application, the drawings that need to be used in the description of the embodiments or the prior art will be briefly described hereinbelow. Obviously, the accompanying drawings in the following description are only some embodiments of the present application. For those skilled in the art, other drawings can be obtained based on these drawings without creative work.

FIG. 1 is a schematic structural diagram of an optoelectronic device provided by a first aspect of embodiments of the present application;

FIG. 2 is a schematic diagram of a quantum dot light-emitting diode in an upright structure provided by an embodiment of the present application; and

FIG. 3 is a schematic diagram of a quantum dot light-emitting diode in an inversion structure provided by an embodiment of the present application.

### DETAILED DESCRIPTION OF THE EMBODIMENTS

In order to make the purposes, technical solutions, and advantages of the present application clearer and more understandable, the present application will be further described in detail hereinafter with reference to the accompanying drawings and embodiments. It should be understood that the embodiments described herein are only intended to illustrate but not to limit the present application.

In the present application, the term “and/or”, which describes the relationship between related objects, means that there can be three relationships, for example, A and/or B, which can mean that A exists alone, A and B exist at the same time, and B exists alone, where A and B can be singular or plural.

In the present application, “at least one” means one or more, and “plurality” means two or more. “At least one item(s) below” or similar expressions thereof refer to any combination of these items, including any combination of single item(s) or plural items(s). For example, “at least one of a, b, or c”, or “at least one of a, b, and c” can mean: a, b, c, a-b (That is, a and b), a-c, b-c, or a-b-c, where a, b, and c can be single or multiple respectively.

It should be understood that, in various embodiments of the present application, the size of the sequence numbers of the processes does not imply the sequence of execution, some or all of the steps may be executed in parallel or sequentially, and the execution sequence of each process should be based on its functions and determined by the internal logic and should not constitute any limitation on the implementation process of the embodiments of the present application. The terms used in the embodiments of the present application are only for the purpose of describing specific embodiments, and are not intended to limit the present application. As used in the embodiments of the present application and the appended claims, the singular forms “a” and “the” are intended to include the plural forms as well, unless otherwise clearly dictated in the context.

In an embodiment of the present application, ΔE_{HTL-HIL}=E_{HOMO,HTL}−E_{HIL}, ΔE_{EML-HTL}=E_{HOMO,EML}−E_{HTL}, all energy level/work function values are absolute values, and a large absolute value of an energy level indicates a deep energy level. A small absolute value of the level indicates a shallow energy level.

In an embodiment of the present application, an amount of hydroxyl groups on the surface of the zinc oxide film is measured by X-ray photoelectron spectroscopy (XPS). Specifically, the zinc oxide film is detected, and a Ols energy spectrum in the result can be divided into three sub-peaks, which are as follows: an OM peak representing a molar concentration of oxygen atoms in the zinc oxide crystal (peak position is between 529 eV and 531 eV), an OV peak representing an oxygen vacancy molar concentration in the zinc oxide crystal (peak position is between 531 eV and 532 eV), an OH peak representing an oxidation of the molar concentration of hydroxyl ligands on the surface of zinc crystals (peak position is between 532 eV and 534 eV). The area ratio between each sub-peak represents the ratio of the molar concentration of different kinds of oxygen atoms in the zinc oxide film. Therefore, the amount of hydroxyl groups on the surface of the zinc oxide film is defined as “OH peak area/OM peak area”, that is, the amount of hydroxyl groups on the surface of the zinc oxide film=the molar concentration of hydroxyl ligands on the surface of the zinc oxide film/the molar concentration of oxygen atoms in the zinc oxide crystal.

The key of the present application is to improve both the service life and the photoelectric efficiency of the QLED device. At present, the characterization of the test of service life of the device is significantly different from the characterization of device efficiency: the time of device efficiency test is usually short, so the device efficiency test characterizes the instantaneous state of the QLED device at the beginning of operation; while the service life of the device characterizes the ability to maintain device efficiency after continuous operation of the device and the device enters a stable state.

At present, based on the existing theoretical system of traditional OLED devices, it is believed that the injection rate of electrons into the light-emitting layer is usually faster than that of holes. Therefore, in order to balance and improve the recombination efficiency of holes and electrons in the light-emitting layer of a QLED device, a hole injection layer is usually arranged in the device, and the injection barrier between two adjacent functional layers is minimized to enhance the hole injection efficiency, thereby improving carrier injection efficiency and reducing interfacial charge accumulation. However, this method can only improve the photoelectric efficiency at the initial instant of the QLED device to a certain extent, but cannot improve the service life of the device in the meanwhile, but even reduces the service life of the device. Through the gradual development and deepening of the research on the mechanism of the QLED device, it is found in the present application that due to the use of quantum dot materials and other nanomaterials having special material surfaces in the QLED device system, QLED has some special mechanisms different from the OLED device system. Such mechanisms are closely related to the performances, especially the service life, of the QLED device.

Specifically, through the research, it is found in the present application that in the initial working state of the QLED device, the injection rate of electrons in the light-emitting layer is faster than that of holes, resulting in the negative charge of the quantum dot material. Such negatively charged state may be maintained due to factors, such as structural properties of quantum dot material, binding effect of surface ligands, and Coulomb blocking effects. However, the negatively charged state of the quantum dot material makes it more and more difficult to inject electrons during the continuous operation of the QLED device, resulting in an imbalance between the actual injection of electrons and holes in the light-emitting layer. When the QLED device continues to light up and work to a stable state, the negatively charged state of the quantum dot material also tends to be stable, that is, the electrons newly captured and bound by the quantum dots reach a dynamic balance with the electrons consumed by the radiative transition. In such condition, the injection rate of electrons into the light-emitting layer is much lower than that in the initial state, and the hole injection rate required to achieve the balance of charge injection in the light-emitting layer is actually relatively low. If the hole injection efficiency is still improved based on the theoretical system of traditional OLED devices, the use of deep energy level hole transport layers can only form an instantaneous balance of charge injection in the initial stage of QLED device operation, and achieve high device efficiency at the initial instant. However, as the QLED device enters a stable working state, excessive hole injection will aggravate the unbalanced state of electrons and holes in the light-emitting layer of the device, and the efficiency of the QLED device cannot be maintained but decreases. And this charge imbalance will continue to increase as the device continues to work, resulting in a corresponding rapid decline in the service life of the QLED device.

Therefore, in order to achieve the balance of carrier injection in the light-emitting layer of the device and obtain a device with higher efficiency and longer service life, the key to fine-tuning the carrier injection of holes and electrons on both sides of the device is as follows: on the one hand, the hole injection rate is regulated to a lower rate, and the electron injection efficiency is improved, so that the hole injection rate and the electron injection rate in the stable working state of the QLED device are balanced, and the recombination efficiency of the QLED device is improved; and on the other hand, since the hole injection rate required for the QLED device in the actual stable operating state is lower than traditionally expected, carrier accumulation easily occurs, causing irreversible damage to the device. Therefore, the influence of carrier accumulation on the service life of the device should be avoided as much as possible, so as to improve the service life of the device.

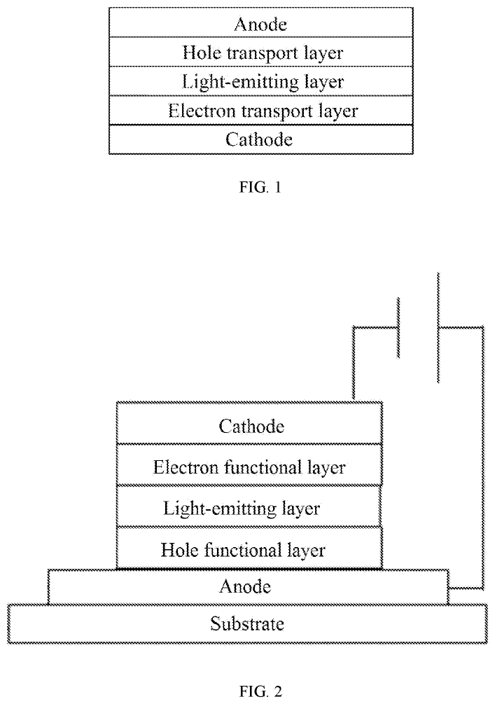

As shown in FIG. 1, a first aspect of embodiments of the present application provides an optoelectronic device. The optoelectronic device, comprises: an anode, a hole transport layer disposed on the anode, a quantum dot light-emitting layer disposed on the hole transport layer, an electron transport layer disposed on the quantum dot light-emitting layer, and a cathode disposed on the electron transport layer. The quantum dot light-emitting layer comprises a quantum dot material in a core-shell structure. A valence band top energy level difference between an shell layer material of the quantum dot material and a hole transport material in the hole transport layer is greater than or equal to 0.5 eV. The electron transport layer comprises a zinc oxide nanomaterial, and a surface of the zinc oxide nanomaterial is bound with an amine/carboxyl ligand having a chain length of between 3 and 8 carbon atoms.

In the optoelectronic device provided by the first aspect of the present application, on the one hand, a valence band top energy level difference between the shell layer material of the quantum dot material and the hole transport material is constructed to be greater than or equal to 0.5 eV, that is, E_{EML-HTL}≥0.5 eV. The hole injection efficiency is reduced by increasing the hole injection barrier, thereby balancing the injection balance of holes and electrons in the light-emitting layer. On the other hand, the zinc oxide nanomaterial having amine/carboxyl ligands with a chain length of between 3 and 8 carbon atoms is bound to the surface of the electron transport layer, and amine group/carboxyl ligands with the chain length of between 3 and 8 carbon atoms are used to replace the hydroxyl ligands on the surface of zinc oxide colloid, which can effectively reduce the content of negatively charged hydroxyl groups on the surface of zinc oxide nanomaterial, and reduce the electronegativity of zinc oxide nanomaterial, thereby reducing the inhibition and hindering of negatively charged hydroxyl groups on electron transport, and therefore improving the efficiency of electron transfer and injection. In addition, the chain length of amine/carboxyl ligands is between 3 and 8 carbon atoms, the chain length is short, the steric hindrance effect is small, and the distance between ZnO nanoparticles and the electron transfer efficiency of the inter-nanoparticles in the electron transport layer film will not be increased.

Based on the energy level characteristics of the current hole transport material and the energy level characteristics of the shell material of quantum dot material, it is found in the present application that at least an energy level barrier of ΔE_{EML-HTL}≥0.5 eV is required to achieve the significant reduction of hole injection efficiency, and to balance the injection efficiency of electrons and holes in the light-emitting layer. In addition, the hole injection barrier of ΔE_{EML-HTL}≥0.5 eV in the present application does not prevent holes from being injected, because the energy level of the shell of the quantum dots will be band-bended under the energized working state, and the carriers can realize the injection via the tunneling effect; therefore, although the increase of the energy level barrier will reduce the carrier injection rate, it will not completely hinder the final injection of carriers.

In the core-shell structure of the quantum dot material in embodiments of the present application, the core material determines the luminescence properties, the shell material protects and facilitates carrier injection, and electrons and holes are injected into the core through the shell layer to emit light. Generally, the band gap of the core is narrower than that of the shell, so that an energy level difference between a valence band of the hole transport material and a valence band of the core of the quantum dot is smaller than an energy level difference between a valence band of the hole transport material and a valence band of the shell of the quantum dot. Therefore, ΔE_{EML-HTL} greater than or equal to 0.5 eV can also ensure the effective injection of hole carriers into the core of the quantum dot material.

In some embodiments, the valence band top energy level difference between the shell layer material of the quantum dot material and the hole transport material in the hole transport layer is between 0.5 eV and 1.7 eV, that is, ΔE_{EML-HTL} is between 0.5 eV and 1.7 eV. The energy level barrier in this range constructed between the shell layer material of the quantum dot material and the hole transport material can be applied to device systems constructed by different hole transport materials and quantum dot materials, to optimize the injection balance between electrons and holes in different device systems. In practical applications, different valence band top energy level differences ΔE_{EML-HTL} can be set according to the specific material properties, and the carrier injection rate of holes and electrons on both sides of the light-emitting layer can be finely adjusted to balance the injection of holes and electrons.

In some specific embodiments, the valence band top energy level difference between the shell layer material of the quantum dot material and the hole transport material is between 0.5 eV and 0.7 eV. In such condition, the applicable hole transport material includes TFB, P12, P15, and the applicable shell layer material of the quantum dot material includes ZnSe, CdS, such as: TFB-ZnSe, P12/P15-CdS and other device systems.

In some specific embodiments, the valence band top energy level difference between the shell layer material of the quantum dot material and the hole transport material is between 0.7 eV and 1.0 eV. In such condition, the applicable hole transport material includes TFB and P09, and the applicable the applicable shell layer material of the quantum dot material includes ZnSe and CdS, such as: P09-ZnSe, TFB-CdS and other device systems.

In some specific embodiments, the valence band top energy level difference between the shell layer material of the quantum dot material and the hole transport material is between 1.0 eV and 1.4 eV, and the applicable hole transport material includes FB, P09, P13, and P14, and the applicable shell layer material of the quantum dot material includes CdS, ZnSe, and ZnS, such as: TFB-ZnS, P09-CdS, P13/P14-ZnSe, and other device systems.

In some specific embodiments, the valence band top energy level difference between the shell layer material of the quantum dot material and the hole transport material is greater than between 1.4 eV and 1.7 eV, and in such condition, the device systems of P09-ZnS and P13/P14-ZnS are applicable.

In the electron transport layer of the embodiments of the present application, zinc oxide nanomaterial having amine groups/carboxyl ligands with a chain length of between 3 and 8 carbon atoms bound on the surface thereof are selected, and zinc oxide nanomaterial having amine groups/carboxyl ligands with a chain length of between 4 and 6 carbon atoms bound on the surface thereof are selected. If the chain length of the amine/carboxyl ligand is too short, the acidity and alkalinity of the amine/carboxyl ligand will increase significantly, and during the preparation process, amine/carboxyl ligand will react with zinc oxide nanoparticles, which will affect the quality of the finally formed zinc oxide film. However, if the chain length of the amine/carboxyl ligand is too long, under the action of steric hindrance, the distance between the zinc oxide nanoparticles in solution and after film formation will increase, and the electron mobility of the zinc oxide electron transport layer after film formation is further reduced, which is contrary to the original design purpose, and thus making the purpose of improving the electron transport efficiency unable to be achieved.

In some embodiments of the present application, zinc oxide nanomaterial having amine/carboxyl ligand with a chain length of between 3 and 8 carbon atoms bound on the surface of zinc oxide nanomaterial can be prepared by a sol-gel method. During the synthesis of zinc oxide gel, a suitable concentration of amino/carboxyl ligand compound solution with a chain length of between 3 and 8 carbons is added to the zinc oxide precursor solution. The ligand exchange reaction is fully carried out by stirring, followed with normal washing, such that zinc oxide nanomaterials having amine/carboxyl ligand with a target chain length attached to the surface thereof can be prepared. In the synthesis process, according to the size of the ligand chain, by controlling the molar ratio of the amine/carboxyl ligand to the precursor, the exchange amount of the amine/carboxyl ligand on the surface of the zinc oxide nanomaterial can be flexibly regulated, thereby regulating the amount of negatively charged hydroxyl groups on the surface of the zinc oxide nanoparticle.

In some embodiments, the zinc oxide nanomaterial is prepared by a sol-gel method according to a ratio of an amine/carboxyl ligand compound to a zinc oxide precursor of (1 to 10):1. In embodiments of the present application, zinc oxide nanomaterial is prepared according to the molar ratio of the amine/carboxyl ligand compound to the zinc oxide precursor of (1-10):1, such that the amount of hydroxyl groups on the surface of the zinc oxide nanoparticles is controlled at a low level, reducing the inhibition and hindering of negatively charged hydroxyl group on the electron transport and therefore improving the efficiency of electron transfer and injection.

In the preparation of zinc oxide nanoparticles in the present application, an appropriate proportion of the amine/carboxyl ligand compound to the zinc oxide can be selected comprehensively according to factors such as the length of the carbon chain of the target ligand, the size of steric hindrance, and the ligand exchange effect with hydroxyl. In some specific embodiments, when the chain length of the amine/carboxyl ligand compound is between 3 and 4 carbon atoms, zinc oxide nanomaterial is prepared according to the molar ratio of the amine/carboxyl ligand compound to the zinc oxide precursor of (4 to 10):1. In other specific embodiments, when the chain length of the amine group/carboxyl ligand compound is between 5 and 7 carbon atoms, the zinc oxide nanomaterial is prepared according to a molar ratio of the amine/carboxyl ligand compound to the zinc oxide precursor of (1 to 5):1.

In some embodiments, the amine/carboxyl ligand compound is at least one selected from the group consisting of propionic acid, propylamine, butyric acid, butylamine, hexanoic acid, hexylamine, pentylamine, and octylamine. The chain length of the amine/carboxyl ligand compound used in the above embodiments of the present application is between 3 and 8 carbon atoms, so as to achieve a good exchange effect with the hydroxyl group ligand on the surface of the zinc oxide nanoparticle.

In some embodiments, the zinc oxide precursor is at least one selected from zinc acetate, zinc nitrate, zinc sulfate, and zinc chloride. In some embodiments, at room temperature, at least one zinc oxide precursor selected from zinc acetate, zinc nitrate, zinc sulfate, and zinc chloride is dissolved in a solvent, such as water, methanol, ethanol, propanol, butanol, ethylene glycol, ethylene glycol monomethyl ether, dimethyl sulfoxide (DMSO), after the temperature is adjusted to between 0° C. and 70° C., potassium hydroxide, sodium hydroxide, lithium hydroxide, tetramethylammonium hydroxide (TMAH), ammonia water, ethanolamine, ethylenediamine and other alkaline solution are added, the mixed solution was continuously stirred/reacted for between 30 mins and 4 hrs while keeping the reaction temperature at between 0° C. and 70° C., a precipitant is added to the mixed solution after the reaction for precipitation. The mixed solution is centrifuged, the precipitate is washed, and a finally obtained precipitate is dissolved in a solvent to obtain a zinc oxide colloidal solution. In an embodiment of the present application, the time point for adding the solution of amine group/carboxyl ligand compound having a chain length of between 3 and 8 carbons can be at an initial stage of the synthesis of the zinc oxide colloidal solution, that is, being added to the zinc oxide precursor solution simultaneously with the alkaline solution; the time point for addition may also be at a middle stage of zinc oxide colloidal solution synthesis, that is, being added to the zinc oxide precursor solution to which alkaline solution has been added; the ligand solution can also be added to the solution when the synthesis of zinc oxide colloidal solution has been finished and the washing is to be conducted, and can also be added to a final zinc oxide colloidal solution obtained after washing. No matter at which stage the ligand solution is added, a resulting solution needs to be stirred for between 10 mins and 2 hrs after the addition, so that the reaction can be fully carried out. More preferably, the stirring time is between 30 mins and 1 hr.

In some embodiments, the electron transport layer is a laminated composite structure, in addition to the zinc oxide nanomaterial having a surface bound with amine group/carboxyl ligands having a chain length of between 3 and 8 carbon atoms, an organic transport material of the electron transport layer is further included. The organic transport materials can achieve energy level regulation in a wide range. Through the co-coordination of metal oxo compound transport materials and organic transport materials in the electron transport layer, the electron transport layer has flexibility in matching between the high electron mobility and the energy level. Effective regulation of the energy level and electron mobility of the electron transport layer is achieved, so as to achieve a sufficient match with hole injection. The electron transport layer in embodiments of the present application can be prepared into a thin film in a light-emitting device by vacuum evaporation or solution method; in which, the solution method includes: inkjet printing, spin coating, spray printing, slot-die printing, screen printing, or the like.

In some embodiments, the electron mobility of the organic transport material is higher than or equal to 10⁻⁴ cm²/Vs. In some embodiments, the organic transport material is at least one selected from 8-quinolinolato-lithium, aluminum octahydroxyquinoline, fullerene derivatives, 3,5-bis(4-tert-butylphenyl)-4-phenyl-4H-1,2,4-triazole, and 1,3,5-tris(1-phenyl-1H-benzimidazol-2-yl)benzene. These organic transport materials can realize energy level regulation in a wide range, which is more conducive to regulating the energy levels of various functional layers of the device and improving the stability and photoelectric conversion efficiency of the device.

In some embodiments, the electron transport layer further includes a metal oxo compound transport layer, in which, the metal oxo compound is at least one selected from titanium oxide, zinc sulfide, and cadmium sulfide. These metal oxo compound transport materials all have high electron transfer efficiency.

In some embodiments, in the electron transport layer, the metal oxo compound transport material has a particle size of smaller than or equal to 10 nm. On the one hand, the metal oxo compound transport material having a small particle size is more conducive to deposition to obtain an electron transport layer film having a dense film layer and a uniform thickness, and improves a bonding tightness with the adjacent functional layer, reduces the interface resistance, and is more conducive to improving the performance of the device. On the other hand, the metal oxide compound transport material with small particle size has a wider band gap, which reduces the quenching of the exciton emission of the quantum dot material and improves the device efficiency.

In some embodiments, the metal oxo compound transport material has an electron mobility of between 10⁻² cm²/Vs and 10⁻³ cm²/Vs. The electron transport material with high mobility can reduce the accumulation of charges in the interface layer and improve the efficiency of electron injection and recombination.

On the one hand, since the hole injection layer in the current device is often used to improve the hole injection efficiency, the QLED device of the embodiment of the present application needs to regulate the hole injection rate to a lower rate in a certain way. Therefore, in some specific embodiments, the optoelectronic device provided in the first aspect of the embodiments of the present application may not be provided with the hole injection layer to enhance the hole injection efficiency.

On the other hand, the arrangement of the hole injection layer in the QLED device can not only improve the hole injection efficiency, but also is the key to regulating the stable and balanced injection of holes, and is also one of the key factors affecting the performance and service life of the device. Therefore, in the embodiments of the present application, by arranging a hole injection layer in the device, the hole injection efficiency in the device can also be controlled and the influence of charge accumulation on the service life of the device can be avoided. Specifically:

Usually, in the research of QLED device performance, more attention is paid to the interface damage caused by charge accumulation on two sides of the light-emitting layer (EML), such as the hole transport layer (HTL) interface or the electron transport layer (ETL) interface, and the exciton quenching in the EML. But in fact, the energy level barrier at the interface between the HIL and the HTL is also prone to charge accumulation, which makes the interface between the HIL and the HTL irreversibly damaged under the action of electric field, resulting in voltage rise of the device and brightness attenuation of the device. Moreover, the voltage rise of the QLED device caused in such condition is significantly different from the voltage rise caused by the charge accumulation at the EML interface as follows: the interface between the HIL and the HTL generates an electric field due to the accumulation of charges, and the irreversible damage will continue to occur as the device continues being powered on, that is, continues deteriorating. However, the charge accumulation at the EML interface is reversible and can reach a certain degree of saturation. Therefore, the interface charge accumulation between the HIL and the HTL has a greater impact on the service life of the device and other performances. Therefore, the charge accumulation at the interface between the HIL and the HTL has a greater impact on the performance of the device, such as the service life of the device.

On the one hand, in order to avoid irreversible damage to service life of the device performance caused by charge accumulation at the interface between the HIL and the HTL, the embodiments of the present application optimize the injection and recombination efficiency of carriers in the QLED device. In a second aspect of the embodiments of the present application, an optoelectronic device is provided on the basis of the embodiments of the first aspect. The optoelectronic device includes a hole transport layer and a first hole injection layer. An absolute value of a difference between a valence band top energy level of the hole transport material and a wok function of the first hole injection material in the first hole injection layer is smaller than or equal to 0.2 eV.

In the optoelectronic device provided by the second aspect of the present application, by limiting |ΔE_{HTL-HIL}| to be smaller than or equal to 0.2 eV, the energy level barrier of hole injection between the HTL and the HIL can be significantly reduced, and the injection efficiency of holes from the anode can be improved, which is conducive to the effective injection of holes from the HIL to the HTL, eliminates the potential barriers and the interface charges, and reduces the overall resistance of the device, thereby avoiding irreversible damage caused by charge accumulation at the interface between the HIL and the HTL, reducing the device driving voltage and improving the service life of the device. If |ΔE_{HTL-HIL}| is greater than 0.2 eV, the energy level barrier at the interface between the HIL and the HTL is prone to charge accumulation, so that the interface between the HIL and the HTL is irreversibly damaged under the action of the electric field, causing the device voltage to rise and the device luminance decay.

In some embodiments, the absolute value of the difference between the valence band top energy level of the hole transport material and the work function of the first hole injection material is 0 eV. In the embodiment of the present application, the selection of |ΔE_{HTL-HIL}| to be 0 is more conducive to the effective injection of holes from the HIL to the HTL, eliminating potential barriers and interface charges, reducing the overall resistance of the device, thereby reducing the driving voltage of the device and improving the service life of the device.

In some embodiments, the absolute value of the work function of the first hole injection material is between 5.3 eV and 5.6 eV, and such work function of the hole injection material is relatively approximate to an absolute value of the valence band energy level (about 5.4 eV) of the existing hole transport material, which is beneficial to control |ΔE_{HTL-HIL}| to be within a lower range, so that the two energy levels are basically flush, thereby eliminating the potential barrier and interface charge, reducing the driving voltage of the device, and improving the service life of the device. In an embodiment of the present application, by selecting the HIL and the HTL materials with suitable energy levels, |ΔE_{HTL-HIL}| is smaller than or equal to 0.2 eV, the energy level barrier from the HIL to the HTL and the charge accumulation at the interface can be effectively eliminated, thereby avoiding the irreversible damage at the interface between the HIL and HTL.

In some embodiments, the mobility of the hole transport material is higher than 1×10⁻⁴ cm²/Vs. In embodiments of the present application, the hole transport materials having the mobility higher than 1×10⁻⁴ cm²/Vs are adopted to ensure hole transport and migration effects, prevent charge accumulation, eliminate interface charges, and better reduce device driving voltage and improve service life of the device.

On the other hand, in order to reduce the hole injection rate in the QLED device, regulate the injection and recombination efficiency of carriers, and avoid irreversible damage to the life performance of the device caused by charge accumulation at the interface between the HIL and the HTL, a third aspect of the embodiments of the present application provides an optoelectronic device based on the embodiments of the first aspect. The optoelectronic device comprises a hole transport layer and a second hole injection layer, in which, a difference between a valence band top energy level of the hole transport material in the hole transport layer and a work function of a second hole injection material in the second hole injection layer is smaller than −0.2 eV.

In the optoelectronic device provided by the third aspect of the present application, by

constructing an injection barrier between the hole transport material and the second hole injection material smaller than −0.2 eV, that is, ΔE_{HTL-HIL}<−0.2 eV, the hole injection barrier from the anode to the HIL is increased, thereby reducing the overall rate of hole injection in the QLED device, and effectively controlling the number of holes entering the QLED device. On the one hand, the rate of hole injection into the light-emitting layer is effectively reduced, which balances the hole-electron injection rate in the light-emitting layer, and improves the carrier recombination efficiency; on the other hand, the excessive hole injection and in turn the charge accumulation at the interface between the HTL and the HIL can be avoided, thereby avoiding irreversible damage to the service life of the device caused by the interface charge accumulation. In addition, a hole blocking barrier is formed from the HTL to the HIL, which prevents holes from diffusing to the HIL layer, improves the utilization rate of holes, and ensures the effective “survival” of holes before being injected into the light-emitting layer. On the basis of ensuring the carrier injection balance in the stable working state of the device, the holes injected in the device are fully and effectively utilized, the luminous efficiency of the device is ensured, and both the device efficiency and service life are improved.

In some embodiments, in the quantum dot material of the core-shell structure contained in the quantum dot light-emitting layer of the optoelectronic device, the valence band top energy level difference between the shell layer material and the hole transport material is greater than 0 eV, that is, ΔE_{EML-HTL}>0, that is, the hole injection barrier exists in the light-emitting layer, together with the barrier between the HTL and the HIL, make the transport layer form a hole carrier trap, which effectively “stores” the accumulated holes without diffusing the holes to other functional layer or interface in addition to the HTL layer, and eliminate the influence of interface charge on the device. On the basis of ensuring the balance of carrier injection in the stable working state of the device, the holes injected in the device are more fully and effectively utilized, the luminous efficiency of the device is ensured, and the improvement of both the efficiency and service life of the device are realized. In some specific embodiments, the valence band top energy level difference between the shell layer material of the quantum dot material and the hole transport material is between 0.5 eV and 1.7 eV, that is, ΔE_{EML-HTL} is between 0.5 eV and 1.7 eV, forming better hole carrier traps. In practical application, the hole carrier traps can control the injection balance of holes and electrons in the light-emitting layer of the device more precisely, and improve the carrier recombination efficiency.

In some embodiments, the difference between the valence band top energy level of the hole transport material and the work function of the second hole injection material is between −0.9 eV and −0.2 eV, that is, the difference value ΔE_{HTL-HL} is between −0.9 eV and −0.2 eV, within such a range, a better balance effect of the hole injection and transport can be realized. If the difference value is lower than −0.9 eV, the hole injection resistance is too large, which will lead to too little hole injection and is not conducive to the balanced injection and effective recombination of holes and electrons in the light-emitting layer; if the potential barrier is greater than −0.2 eV, the holes are prone to be accumulated at the interface, and the utilization rate is not high.

In some embodiments, an absolute value of the work function of the second hole injection material is between 5.4 eV and 5.8 eV. In the embodiments of the present application, the absolute value of the work function of the second hole injection material is between 5.4 eV and 5.8 eV, the range of which is favorable for forming a hole blocking barrier having an energy level difference of smaller than −0.2 eV with the hole transport material. Specifically, the absolute value of the valence band of the conventional hole transport material is about between 5.3 and 5.4 eV, and the second hole injection material having the absolute value of the work function greater than or equal to 5.4 eV can form a negative energy level difference of smaller than −0.2 eV with the conventional hole transport material, thereby forming a hole blocking barrier, optimizing the hole injection rate, and improving the hole utilization rate.

In some embodiments, the mobility of the hole transport material is higher than 1×10⁻⁴ cm²/Vs. In the embodiments of the present application, the hole transport materials having the mobility of higher than 1×10⁻⁴ cm²/Vs are used to ensure the transport and migration effect of holes, prevent the charge accumulation, eliminate the interface charge, and better reduce the device driving voltage and improve the service life of the device.

In the embodiments of the second aspect and the third aspect of the present application, the hole injection material is selected from a metal oxide material. That is, in some embodiments, when the optoelectronic device includes a first hole injection layer, the first hole injection material in the first hole injection layer is selected from metal oxide materials. In other specific embodiments, when the optoelectronic device includes a second hole injection layer, the second hole injection material in the second hole injection layer is selected from metal oxide materials. In the above embodiments of the present application, the metal oxide material used as the hole injection material has better stability and is not acidic, which not only meets the requirements for hole injection in the above embodiments, but also does not negatively affect adjacent functional layers. It is avoided the degradation of the service life of the device caused by the thermal effect or the electrical effect damage of the organic hole injection material during the working process of the device, and in the meanwhile, it is avoided the damage to the adjacent functional layer caused by the acidity of the organic hole injection material.

In some embodiments, the metal oxide material includes at least one metal nanomaterial selected from tungsten oxide, molybdenum oxide, vanadium oxide, nickel oxide, and copper oxide. These metal nanomaterials not only have better stability, but also have no acidity, and in the actual application process, the size of the work function can be adjusted to realize the construction of energy level barriers of different sizes with the hole transport layer, which is beneficial to control hole injection and transport, improve the carrier recombination efficiency, and avoid the negative impact of the charge accumulation on service life of the device.

In some embodiments, the particle size of the metal oxide material is between 2 and 10 nm, and the metal oxide material having a small particle size is more conducive to depositing a film having a dense film layer and a uniform thickness, which improves the bonding with the adjacent functional layer and reduces the interface resistance, thereby being more conducive to improving the device performance.

In other embodiments, the hole injection material can also be poly(3,4-ethylenedioxythiophene)-polystyrenesulfonic acid (PEDOT: PSS), HIL2, HIL1-1, HIL1-2, copper phthalocyanine (CuPc), 2,3,5,6-tetrafluoro-7,7′,8,8′-tetracyanoquinone-dimethane (F4-TCNQ), 2,3,6,7,10,11-hexacyano-1,4,5,8,9,12-hexaazatriphenylene (HATCN) and other organic hole injection materials. Among them, PEDOT: PSS contains an organic molecule having a structural formula of:

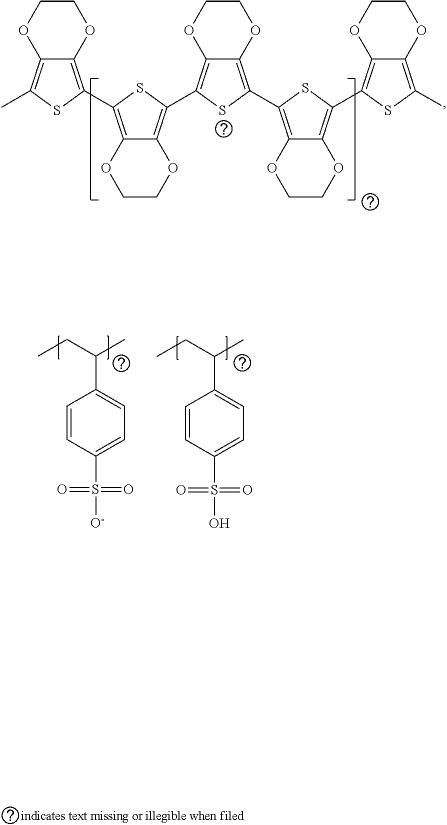

and a work function of −5.1 eV; HIL2 contains an organic molecule having structural formulas of:

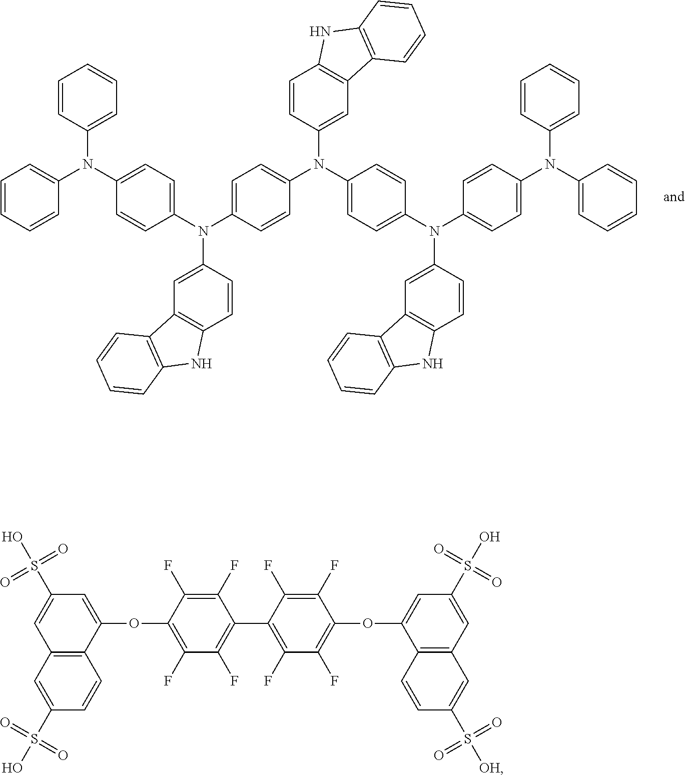 [SMILES: c1ccc(N(c2ccccc2)c2ccc(N(c3ccc(N(c4ccc(N(c5ccc(N(c6ccccc6)c6ccccc6)cc5)c5ccc6[nH]c7ccccc7c6c5)cc4)c4ccc5[nH]c6ccccc6c5c4)cc3)c3ccc4[nH]c5ccccc5c4c3)cc2)cc1 ; O=S(=O)(O)c1ccc2c(Oc3c(F)c(F)c(-c4c(F)c(F)c(Oc5cc(S(=O)(=O)O)cc6cc(S(=O)(=O)O)ccc56)c(F)c4F)c(F)c3F)cc(S(=O)(=O)O)cc2c1]

and a work function of −5.6 eV; HIL1-1 and HIL1-2 both contain organic molecule having structural formulas of:

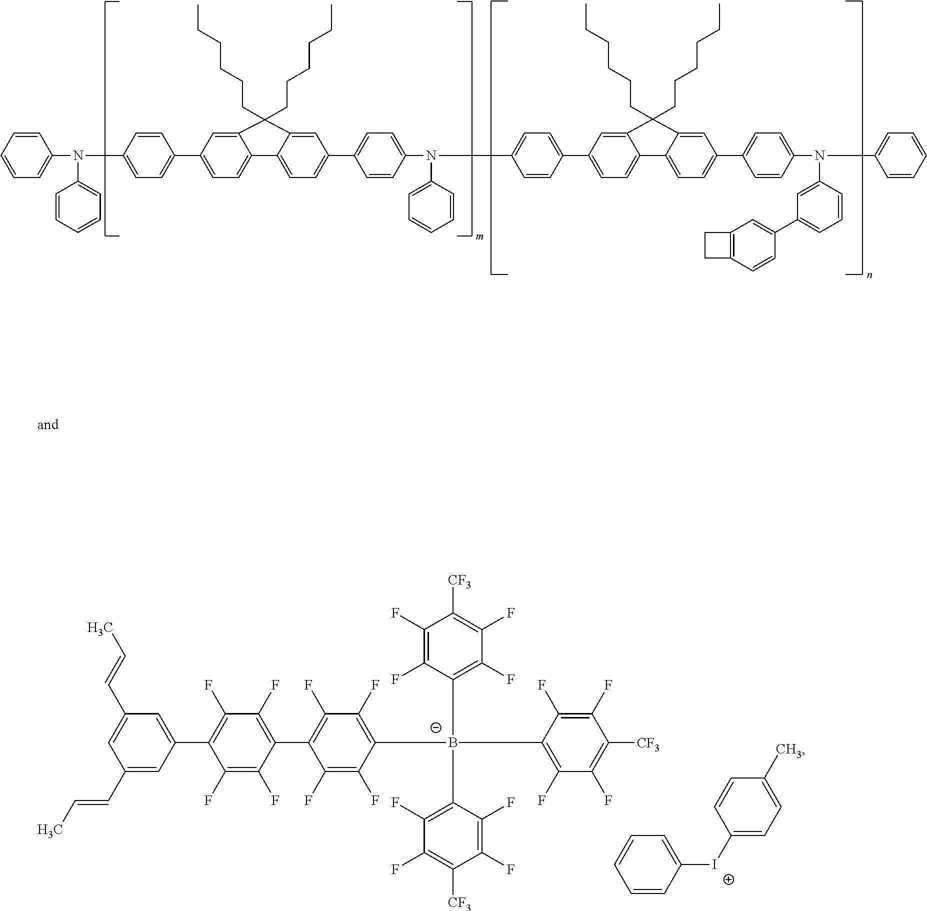

a work function of HIL1-1 is −5.4 eV, and a work function of HIL1-2 is −5.3 eV.

In some embodiments, the first hole injection layer has a thickness of between 10 nm and 150 nm. In other embodiments, the second hole injection layer has a thickness of between 10 nm and 150 nm. The thickness of the hole injection layer of the present application can be flexibly adjusted according to actual application requirements, and the hole injection rate can also be better adjusted by adjusting the thickness of the hole injection layer.

In some embodiments, the hole transport material is at least one selected from TFB, poly-TPD, P11, P09, P13, P15, and P12. In other embodiments, the mobility of the hole transport material is higher than 1×10⁻⁴ cm²/Vs. The hole transport material provided by the above embodiments of the present application can not only build a hole injection barrier having an energy level difference greater than or equal to 0.5 eV with the shell layer material of the quantum dot material, but also can effectively ensure the migration rate of holes, avoid the charge accumulation caused by slow migration rate, and improve the service life of the device. Specifically, in embodiments of the present application, it is achieved the purpose of constructing an energy level barrier with ΔE_{EML-HTL} greater than or equal to 0.5 eV, reducing the hole injection rate in the QLED device, regulating the injection and recombination efficiency of carriers, and avoiding irreversible damage to service life of the device caused by charge accumulation at the interface between the HIL and the HTL. In some embodiments, a fourth aspect of the present application provides an optoelectronic device, the hole transport layer of the optoelectronic device comprises at least two hole transport materials, in which, an absolute value of the valence band top energy level of at least one hole transport material is smaller than or equal to 5.3 eV, and an absolute value of the valence band top energy level of at least one hole transport material is greater than 5.3 eV.

The hole transport layer of the optoelectronic device provided by the fourth aspect of the present application is a hybrid material, in which, the valence band top energy level of at least one hole transport material is smaller than or equal to 5.3 eV, while the shell energy level of conventional quantum dot light-emitting materials is often relatively deep (6.0 eV or deeper), therefore, an energy level difference of 0.5 eV or higher is formed between the hole transport material having a shallow energy level and the quantum dot shell material. In the hole transport layer, through the combination of shallow-energy level materials and deep-energy level materials, the fine control of the hole injection barrier between the hole transport material and the quantum dot shell layer can be achieved, in the meanwhile, the hole mobility in the HTL layer can be modulated through hole transport materials with different deep and shallow energy levels, to realize the energy level barrier of ΔE_{EML-HTL} greater than or equal to 0.5 eV. By increasing the hole injection barrier and reducing the hole injection efficiency, the injection balance of holes and electrons in the light-emitting layer is balanced, the luminous efficiency of the device is improved, and meanwhile, the impact of the charge accumulation on the service life of the device is avoided.

In some embodiments, the hole transport layer further includes a hole transport material having an absolute value of a valence band top energy level of greater than 5.3 eV and smaller than 5.8 eV. In some embodiments, the hole transport layer further includes a hole transport material having the absolute value of the valence band top energy level of greater than or equal to 5.8 eV. In other embodiments, the hole transport layer also includes the hole transport material having an absolute value of the valence band top energy level of greater than 5.3 eV and smaller than 5.8 eV and the hole transport material having the absolute value of the valence band top energy level of greater than or equal to 5.8 eV. In embodiments of the present application, by a combination and matching of the shallow-energy level material and the deep-energy level material, the hole injection barrier can be flexibly adjusted according to practical application requirements, device systems and other factors, so that the injection energy level barrier of holes to the light-emitting material is greater than or equal to 0.5 eV, reducing the injection efficiency of holes, so as to balance the injection balance of holes and electrons in the light-emitting layer, and the application is flexible and convenient.

In some embodiments, when the hole transport layer includes the hole transport material having the valence band top energy level greater than 5.3 eV and smaller than 5.8 eV, the electron transport layer of the optoelectronic device is selected to include at least one of an organic electron transport material layer, a metal oxide nanoparticle layer, such as ZnO nanoparticles and the like, and a sputter deposited metal oxide layer. In an embodiment of the present application, when the hole transport layer includes at least one of: the hole transport material having an absolute value of the valence band top energy level of smaller than or equal to 5.3 eV, and the hole transport material having the absolute value of the valence band top energy level of greater than 5.3 eV and smaller than 5.8 eV, in such condition, the hole transport layer has a relatively moderate valence band top energy level and hole mobility, which can be well matched with conventional metal oxides such as ZnO or organic electron transport materials, thus being beneficial to the regulation of the charge balance between holes and electrons.

In some embodiments, when the hole transport layer includes a hole transport material having the valence band top energy level greater than or equal to 5.8 eV, the electron transport layer of the optoelectronic device is selected to include: metal oxide nanoparticles, which are selected to be metal oxide nanoparticles with relatively few surface groups. In embodiments of the present application, when the hole transport layer includes a hole transport material having the valence band top energy level of greater than 5.8 eV, the energy level and mobility thereof are both relatively greatly different from those in the above hole transport material having a shallow valence band top energy level of smaller than or equal to 5.3 eV, and continuous regulation in a large window range can be achieved through different mixing ratios, which is suitable for QLED device system that has relatively large changes in electron injection and transport from an initial state of the device to a steady state after continuous operation, for example, metal oxide nanoparticles with fewer groups attached to the surfaces thereof

In some embodiments, in the hole transport layer, a weight percentage of the hole transport material having the absolute value of the valence band top energy level of smaller than or equal to 5.3 eV is between 30 wt. % and 90 wt. %. Such a content in percentage of the shallow-energy level hole transport material can ensure to form a hole injection barrier greater than or equal to 0.5 eV with the shell layer of the light-emitting material. In practical applications, the mixing ratio of materials of each energy level can be flexibly adjusted according to the depth of the material energy level.

In some embodiments, in the hole transport layer, the mobility of at least one hole transport material is higher than 1×10⁻³ cm²/Vs, and the high mobility of the hole transport material in the embodiments of the present application ensures the transport and migration performance of holes, and avoids the accumulation of holes at the interface which would otherwise affect the device performance. In addition, the valence band top energy level of the hole transport material having high hole mobility is relatively shallow, which also ensures the formation of a suitable energy level difference with the quantum dot shell material.

In some embodiments, the mobility of at least one hole transport material in the hole transport layer is higher than 1×10⁻² cm²/Vs. In other specific embodiments, in the hole transport layer, the mobility of each hole transport material is higher than 1×10⁻³ cm²/Vs. The above embodiments of the present application optimize the mobility of the hole transport material, ensure the hole transport efficiency, avoid charge accumulation which would otherwise affect the device performance, and ensure the combination of deep and shallow hole transport materials in the hole transport layer. The injection barrier of the hole constructed in this way ensures the formation of an energy level barrier having the ΔE_{EML-HTL} of greater than or equal to 0.5 eV, and optimizes the injection balance and recombination efficiency of carriers in the QLED device.

In some embodiments of the present application, in order to construct an energy level barrier having ΔE_{EML-HTL} of greater than or equal to 0.5 eV, reduce the hole injection rate in the QLED device, regulate the injection and recombination efficiency of carriers, and avoid irreversible damage to service life of the device caused by charge accumulation at the interface between the HIL and the HTL. In some embodiments, a fifth aspect of the present application provides an optoelectronic device, the hole transport layer of the optoelectronic device comprises at least two hole transport materials, in which, absolute values of the valence band top energy levels of the hole transport materials are all smaller than or equal to 5.3 eV.

The hole transport layer of the optoelectronic device provided by the fifth aspect of the present application is a mixed material, and the valence band top energy levels of the hole transport materials are all smaller than or equal to 5.3 eV, which can form an energy level difference of greater than or equal to 0.5 eV with the quantum dot light-emitting material having a deeper shell energy level. A finer control of the hole injection barrier between the quantum dot shell layers in the HTL and the EML is achieved, making the device having a ΔE_{EML-HTL}≥0.5 eV. Therefore, after the QLED device enters a stable working state, the charge injection balance and the device efficiency are maintained, and the service life of the device is optimized. In addition, the hole mobility of the mixed hole transport layer can also be finely regulated by different mixing ratios by using the different hole nobilities of the hole transport materials having the hole transport materials with shallow valence band top energy levels.

In some embodiments, in the hole transport layer, the weight percentage of each hole transport material is between 5 wt. % and 95 wt. %. Based on mixing of hole transport material having different energy levels and nobilities, the hole mobility and injection barrier of the mixed hole transport layer can be better controlled.

In some embodiments, in the hole transport layer, the mobility of at least one hole transport material is higher than 1×10⁻³ cm²/Vs, and the hole transport material with high hole mobility has a relatively shallow valence band top energy level. The mobility of the hole transport material is limited, and the high mobility ensures the transport and migration performance of holes, as well as the formation of a more suitable injection barrier, so as to avoid the accumulation of holes at the interface and affect the device performance. In some embodiments, the mobility of at least one hole transport material in the hole transport layer is higher than 1×10⁻² cm²/Vs. In some embodiments, the mobility of each hole transport material in the hole transport layer is higher than 1×10⁻³ cm²/Vs.

In some embodiments, when the valence band top energy levels of the hole transport materials in the hole transport layer are all smaller than or equal to 5.3 eV, the selection of the electron transport layer of the optoelectronic device includes: surface-passivated metal oxide nanoparticles, and the selected surface is sufficient modification of passivated metal oxide nanoparticles. In embodiments of the present application, when the valence band top energy levels of the hole transport materials in the hole transport layer are all smaller than or equal to 5.3 eV, it is necessary to correspond to the material with small changes in electron injection and transport. In such condition, it is suitable for QLED device system that has relatively small changes in electron injection and transport from an initial state of the device to a steady state after continuous operation, for example, metal oxide nanoparticles with adequate surface modification and passivation.

In the optoelectronic devices of the above embodiments of the present application, the hole transport material is at least one selected from a polymer containing an aniline group and a copolymer containing a fluorene group and an aniline group, and such hole transport material is advantageous in high hole transport efficiency, good stability, and easy access. In the actual application process, a hole transport material having suitable energy level and mobility can be selected according to the actual application requirements, specifically:

In some specific embodiments, when a hole material having an absolute value of valence band top energy level of smaller than or equal to 5.3 eV is required in an optoelectronic device, the hole transport material having the absolute value of valence band top energy level smaller than or equal to 5.3 eV can be at least one selected from P09 and P13. Among them, P13 has a structural formula of:

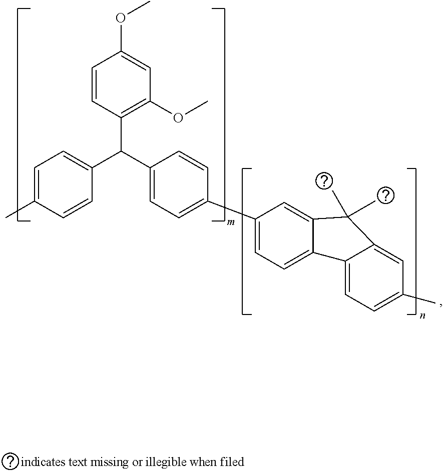

and P09 has a structural formula of:

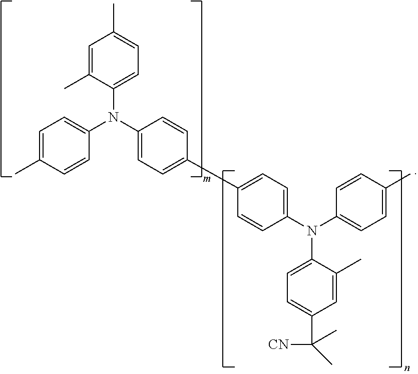

In other specific embodiments, when a hole material having the absolute value of the valence band top energy level of greater than 5.3 eV and smaller than 5.8 eV is required in the optoelectronic device, the holes having the absolute value of the valence band top energy level of greater than 5.3 eV and smaller than 5.8 eV includes at least one of TFB, poly-TPD, and P11. Among them, P11 has a structural formula of:

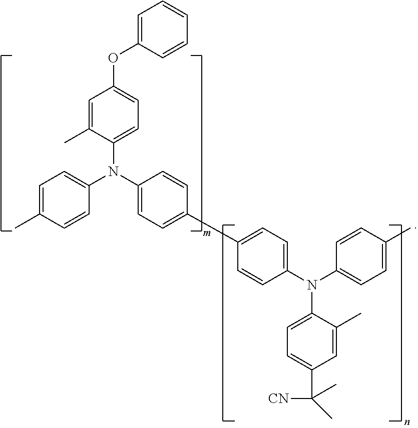

The poly-TPD has a structural formula of:

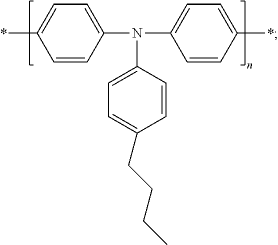

and TFB has a structural formula of:

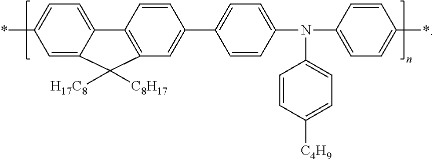

In other specific embodiments, when a hole material having an absolute value of valence band top energy level of greater than or equal to 5.8 eV is required in an optoelectronic device, the hole transport material having the absolute value of the valence band top energy level of greater than or equal to 5.8 eV includes at least one of P15 and P12. Among them, the P12 has a structural formula of:

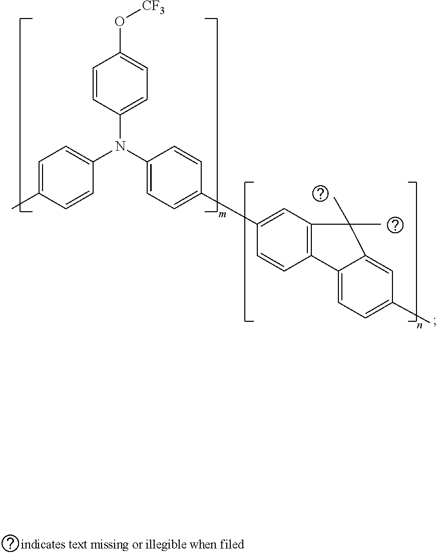

and P15 has a structural formula of:

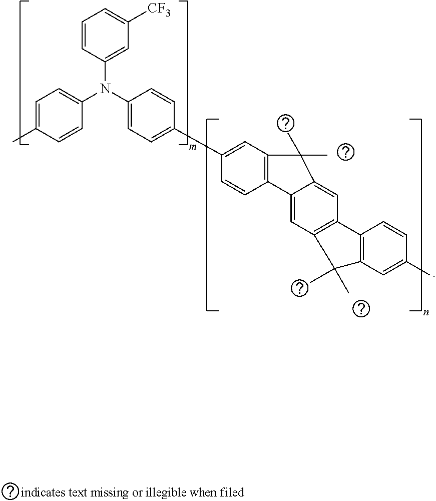

In some embodiments, the mobility of the hole transport material is higher than 1×10⁻⁴ cm²/Vs, and the high mobility ensures the transport and migration performance of holes and avoids the influence of charge accumulation on the service life of the device.

In the above-mentioned embodiments of the present application, the quantum dot material of the core-shell structure further includes a core, and an intermediate shell layer located between the core and the shell layer. The valence band top energy level of the core material is shallower than the valence band top energy level of the shell layer. The valence band top energy level of the intermediate shell material is between the valence band top energy level of the core material and the valence band top energy level of the shell layer material. In the quantum dot materials of the core-shell structure in embodiments of the present application, the core material determines the luminescence properties, the shell material plays the role of protection and facilitates the injection of carriers, and the intermediate shell layer having the valence band between that of the core and that of the shell layer plays an intermediate transition role, which is beneficial for the carrier injection. The intermediate shell layer can form a stepped energy level transition from the core to the shell layer, which helps to achieve effective carrier injection, effective confinement, and reduction in lattice interface flickering.

In some embodiments, the shell layer of the quantum dot material includes an alloy material formed by at least one or at least two of CdS, ZnSe, ZnTe, ZnS, ZnSeS, CdZnS, and PbS. These shell layer materials not only protect and facilitate the injection of carriers into the quantum dot core for light emission, but also form an energy level barrier having the ΔE_{EML-HTL} greater than or equal to 0.5 eV with the HTL layer material. Therefore, the injection balance of holes and electrons in the light-emitting layer is balanced, the luminous efficiency of the device is improved, and the influence of charge accumulation on the service life of the device is avoided.

In some embodiments, the core of the quantum dot material includes at least one of CdSe, CdZnSe, CdZnS, CdSeS, CdZnSeS, InP, InGaP, GaN, GaP, ZnSe, ZnTe, and ZnTeSe. The luminescent properties of quantum dot materials are related to the core materials. These materials ensure that QLED devices can emit light in the visible light range of between 400 nm and 700 nm, which not only meets the range required for the application of optoelectronic display devices, but also the beneficial effects achieved by the energy level relationship of these materials can be better reflected.

In some embodiments, the intermediate shell material is at least one selected from CdZnSe, ZnSe, CdZnS, CdZnSeS, CdS, and CdSeS. In an embodiment of the present application, the composition of the intermediate shell layer preferably forms a continuous and natural transition from the core to the outer layer, which helps to achieve the least lattice mismatch and minimum lattice defects among the core, the intermediate shell layer, and the shell layer, so as to achieve the optimal luminescence properties of the core-shell quantum dot material itself

In some embodiments, the emission peak wavelength range of the quantum dot material is between 400 nm and 700 nm. On the one hand, this wavelength range is required for the application of optoelectronic display devices; on the other hand, the beneficial effect of the light-emitting layer of the device realized by the energy level relationship within the wavelength range can be better reflected.

In some embodiments, the thickness of the shell layer of the quantum dot material is between 0.2 nm and 6.0 nm, which covers the thickness of the conventional shell and can be widely used in QLED devices of different systems. If the thickness of the shell layer is too large, the rate at which carriers are injected into the light-emitting quantum dots through the tunneling effect will decrease; and if the thickness of the shell layer is too small, the shell layer material cannot sufficiently protect and passivate the core material, which affects the luminescence and stability properties of quantum dot materials.

In the above-mentioned embodiments of the present application, the optoelectronic device further includes an electron transport layer, and the electron transport material in the electron transport layer is at least one selected from metal oxo compound transport materials and organic transport materials. Among them, the metal oxide material generally has a high electron mobility, and can be prepared into a thin film in the QLED device by solution method or vacuum sputtering method. The organic electron transport layer materials can achieve energy level regulation in a wide range, and can be prepared into a thin film in QLED devices by vacuum evaporation or solution method. The solution method includes: inkjet printing, spin coating, spray printing, slot-die printing, screen printing, or the like. More suitable electron transport materials can be flexibly selected according to actual application requirements.

In some embodiments, the metal oxo compound transport material is at least one selected from zinc oxide, titanium oxide, zinc sulfide, and cadmium sulfide. These metal oxo compound transport materials used in the above embodiments of the present application all have high electron transfer efficiency. In some embodiments, in order to improve electron transfer efficiency, the metal oxo compound transport material is at least one selected from zinc oxide, titanium oxide, zinc sulfide, and cadmium sulfide doped with a metal element, in which, the metal element includes at least one of aluminum, magnesium, lithium, lanthanum, yttrium, manganese, gallium, iron, chromium, and cobalt, in which, these metal elements can improve the electron transfer efficiency of the material.

In some embodiments, the particle size of the metal oxo compound transport material is smaller than or equal to 10 nm. On the one hand, the metal oxy compound transport material having a small particle size is more conducive to the deposition of electron transport layer film having a dense film layer and a uniform thickness, improving the tightness of bonding with the adjacent functional layers, reducing the interface resistance, and is more conducive to improving the performance of the device. On the other hand, the metal oxide compound transport material having the small particle size has a wider band gap, which reduces the quenching of the exciton emission of the quantum dot material and improves the device efficiency.

In some embodiments, the electron mobility of the metal oxo compound transport material is between 10⁻² cm²/Vs and 10⁻³ cm²/Vs. The electron transport material having high mobility can reduce the accumulation of charges in the interface layer and improve the efficiency of electron injection and recombination efficiency.

In some embodiments, the electron mobility of the organic transport material is not smaller than 10⁻⁴ cm^{2 /}Vs. In some embodiments, the organic transport material is at least one selected from NaF, LiF, CsF, 8-hydroxyquinoline-lithium, Cs₂CO₃, and Alq₃. These organic transport materials can realize energy level regulation in a wide range, which is more conducive to regulating the energy levels of various functional layers of the device and improving the stability and photoelectric conversion efficiency of the device.

In some embodiments, the electron transport layer is a laminated composite structure, which includes at least two sub-electron transport layers. By selecting sub-electron transport layers with different transport and migration efficiencies and energy level regulation characteristics, the performance of the electron transport layer can be regulated more flexibly, so as to better optimize device performance.

In some embodiments, in the electron transport layer, the material of at least one sub-electron transport layer is a metal oxo compound transport material. In some embodiments, in the electron transport layer, all sub-electron transport layers are metal oxides, and the metal oxide materials of different sub-electron transport layers may be the same or different. That is, in the multilayer electron transport layer in which all the sub-electron transport layers are metal oxides, there may be a sub-electron transport layer comprising at least one layer of metal oxide nanoparticles and at least one layer of non-nanoparticle type metal oxides, there may be sub-electron transport layers that are respectively doped and intrinsic metal oxides (for example, Mg-doped ZnO+intrinsic ZnO), there may also be sub-electron transport layers all belonging the same metal oxide nanoparticles. When the sub-electron transport layers are all of the same metal oxide nanoparticle, the electron nobilities of different sub-electron transport layers may be the same or different.

In some embodiments, in the electron transport layer, the material of at least one sub-electron transport layer is an organic transport material. In some embodiments, in the electron transport layer, the material of at least one sub-electron transport layer is a metal oxo compound transport material, the material of at least one sub-electron transport layer is an organic transport material, and the metal oxide of different sub-electron transport layers can be the same or different; the metal oxide materials are selected as nanoparticles of the corresponding metal oxide. The electron transport layer has both high electron mobility and flexibility of energy level matching through the co-coordination of the metal oxo compound transport material and the organic transport material in the electron transport layer. Effective regulation of the energy level and the electron mobility of the electron transport layer is achieved, so as to achieve a sufficient match with the hole injection. In some specific embodiments, the electron transport layer comprising multiple sub-electron transport layers may be a combination of ZnO nanoparticles+NaF, a combination of Mg-doped ZnO nanoparticles+NaF, or other laminated composite structures.

As in the quantum dot material of the core-shell structure, the core material determines the luminescence properties of the quantum dot material, and the shell material plays a protective role and is conducive to carrier injection. After the material of the shell layer is determined, the thickness of the shell layer and the valence band top energy level of the hole transport material can be adjusted, so that the valence band top energy level difference between the shell layer material of the quantum dot material and the hole transport material is greater than or equal to 0.5 eV, that is, the expected injection barrier is constructed, E_{EML-HTL}≥0.5 eV, the balance of electron and hole injection efficiency in the light-emitting layer is optimized, and the device efficiency and service life are improved.

In the above embodiments of the present application, the device is not limited by the device structure, and may be a device in an upright structure or a device in an inversion structure.

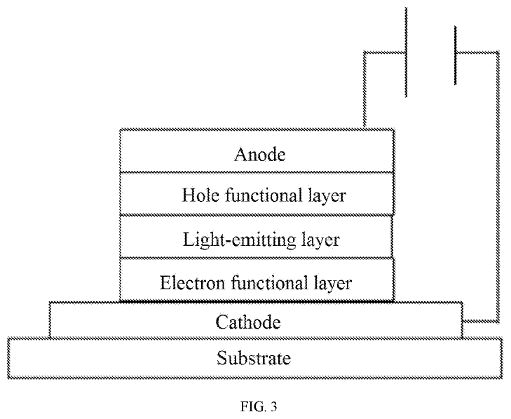

In an embodiment, the upright structured optoelectronic device includes a stacked structure of oppositely disposed anode and cathode, a light-emitting layer disposed between the anode and the cathode, and a substrate on which the anode disposed. In some embodiments, a hole functional layer, such as a hole injection layer and a hole transport layer, can also be arranged between the anode and the light-emitting layer; and an electron functional layer, such as an electron transport layer and an electron injection layer, can also be arranged between the cathode and the light-emitting layer, as shown in FIG. 2. In some embodiments of specific upright structure devices, the optoelectronic device includes a substrate, an anode disposed on the surface of the substrate, a hole transport layer disposed on the surface of the anode, a light-emitting layer disposed on the surface of the hole transport layer, an electron transport layer disposed on the surface of the layer, and a cathode disposed on the surface of the electron transport layer.

In an embodiment, the inversion structured optoelectronic device comprises a stacked structure of oppositely disposed anode and cathode, a light-emitting layer disposed between the anode and the cathode, and a substrate on which the cathode is disposed. A hole functional layer, such as a hole injection layer and a hole transport layer, can also be arranged between the anode and the light-emitting layer; and an electron functional layer, such as an electron transport layer and an electron injection layer, can also be arranged between the cathode and the light-emitting layer, as shown in FIG. 3. In some embodiments of the inversion structured device, the optoelectronic device includes: a substrate, a cathode disposed on a surface of the substrate, an electron transport layer disposed on a surface of the cathode, a light-emitting layer disposed on a surface of the electron transport layer, a hole transport layer disposed on a surface of the light-emitting layer, and an anode disposed on a surface of the hole transport layer.

In some embodiments, the choice of the substrate is not limited, and a rigid substrate or a flexible substrate may be used. In some specific embodiments, the rigid substrate includes, but is not limited to, one or more of glass and metal foil. In some specific embodiments, the flexible substrate includes, but is not limited to, one or more of a poalkaline solutionthylene terephthalate (PET), a poalkaline solutionthylene terephthalate (PEN), a poalkaline solutiontheretherketone (PEEK), a polystyrene (PS), a poalkaline solutionthersulfone (PES), a polycarbonate (PC), a polyarylate (PAT), a polyarylate (PAR), a polyimide (PI), a polyvinyl chloride (PV), a polyethylene (PE), a polyvinylpyrrolidone (PVP), and a textile fiber.

In some embodiments, the choice of anode material is not limited and can be selected from doped metal oxides, including, but not limited to, one or more of indium doped tin oxide (ITO), fluorine doped tin oxide (FTO), antimony doped tin oxide (ATO), aluminum-doped zinc oxide (AZO), gallium-doped zinc oxide (GZO), indium-doped zinc oxide (IZO), magnesium-doped zinc oxide (MZO), aluminum-doped magnesium oxide (AMO), and can also be selected from a composite electrode including doped or undoped transparent metal oxides sandwiching a metal, including, but not limited to, one or more of AZO/Ag/AZO, AZO/Al/AZO, ITO/Ag/ITO, ITO/Al/ Among ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂.

In some embodiments, the cathode material may be one or more of various conductive carbon materials, conductive metal oxide materials, and metallic materials. In some specific embodiments, conductive carbon materials include, but are not limited to, doped or undoped carbon nanotubes, doped or undoped graphene, doped or undoped graphene oxide, C60, graphite, carbon fiber, porous carbon, or a mixture thereof. In some specific embodiments, the conductive metal oxide material includes, but is not limited to, ITO, FTO, ATO, AZO, or a mixture thereof

In some specific embodiments, the metal materials include, but are not limited to, Al, Ag, Cu, Mo, Au, or an alloy thereof; A form of the metal material includes, but is not limited to, a dense film, a nanowire, a nanosphere, a nanometer rod, a nano cone, a nano hollow sphere, or a mixture thereof. The cathode is Ag or Al.

In some embodiments, the quantum dot light-emitting layer has a thickness of between 8 nm and 100 nm. In some embodiments, the hole transport layer has a thickness of between 10 nm and 150 nm. In some embodiments, the electron transport layer has a thickness of between 10 nm and 200 nm. In practical applications, the electronic functional layer, the light-emitting layer, and the hole functional layer in the device can be provided with appropriate functional layers according to the characteristics of the device in the above embodiments.

The preparation of the optoelectronic device in embodiments of the present application includes the following steps:
In step S10, a substrate on which an anode is deposited is obtained;
In step S20, a hole injection layer is grown on a surface of the anode;
In step S30, a hole transport layer is grown on a surface of the hole injection layer;
In step S40, a quantum dot light-emitting layer is deposited on the hole transport layer; and
In step S50, an electron transport layer is finally deposited on the quantum dot light-emitting layer, and a cathode is evaporated on the electron transport layer, so as to obtain an optoelectronic device.

Specifically, in step S10, the ITO substrate needs to undergo a pretreatment process, and the steps include: washing the ITO conductive glass with a detergent to preliminarily remove stains existing on the surface, and then ultrasonic washing the ITP conductive glass sequentially in deionized water, acetone, anhydrous ethanol, and deionized water, with each solution for 20 mins, so as to remove impurities on the surface, and finally drying the ITP conductive glass with high-purity nitrogen, to obtain the ITO positive electrode.

Specifically, in step S20, the step of growing the hole injection layer includes: preparing a metal oxide and other materials into a film in the QLED device by a solution method, a vacuum sputtering method, and a vacuum evaporation method; in which, the solution method includes: inkjet printing, spin coating, spray printing, slot-die printing, screen printing, or the like.

Specifically, in step S30, the step of growing the hole transport layer includes: placing the ITO substrate on a spin coater, and using the prepared solution of the hole transport material to spin to form a film; adjusting the concentration of the solution and the spin coating speed and spin coating time to control the thickness of the film, and performing thermal annealing at an appropriate temperature.

Specifically, in step S40, the step of depositing the quantum dot light-emitting layer on the hole transport layer includes: placing the substrate on which the hole transport layer has been spin-coated on a spin coater, and spin-coating a solution of a prepared light-emitting substance with a certain concentration into a film, controlling a thickness of the light-emitting layer to about between 20 nm and 60 nm by adjusting the concentration of the solution, the spin coating speed and the spin coating time, and drying at an appropriate temperature.

Specifically, in step S50, the step of depositing the electron transport layer on the quantum dot light-emitting layer includes: placing the substrate on which the quantum dot light-emitting layer has been spin-coated on the spin coater, and spin-coating a prepared electron transport composite material with a certain concentration to form a film by drip coating, spin coating, soaking, coating, printing, evaporation, and other processes, and controlling a thickness of the electron transport layer to about between 20 nm and 60 nm, by adjusting a concentration of the solution, a spin coating speed (for example, a rotation speed is between 3000 rpm and 5000 rpm), and a spin-coating time, annealing under a conditions of between 150° C. and 200° C. to form a film, and fully removing the solvent.

Specifically, in step S50, the step of preparing the cathode includes: placing the substrate on which all functional layers have been deposited into an evaporation chamber, and thermally evaporating a layer of metal silver or aluminum having a thickness of between 60 nm and 100 nm as a cathode through a mask plate.

In some embodiments, the preparation method of an optoelectronic device further includes: encapsulating the laminated optoelectronic device, in which, the curing resin used in the encapsulation is acrylic resin, acrylate resin, or epoxy resin; the resin curing adopts UV irradiation, heat or a combination of both. The encapsulation process can be done by conventional machine encapsulation or manual encapsulation. In the packaging process environment, the oxygen content and water content are both lower than 0.1 ppm to ensure the stability of the device.

In some embodiments, the preparation method of the optoelectronic device further includes, after encapsulating the optoelectronic device, introducing one or more processes including ultraviolet irradiation, heating, positive and negative pressure, applied electric field, and applied magnetic field; and the atmosphere during the above one or more processes can be air or an inert atmosphere.

In order to make the above-mentioned implementation details and operations of the present application clearly understood by those skilled in the art, as well as to significantly reflect the improved performance of the optoelectronic devices in the embodiments of the present application, the above-mentioned technical solutions are exemplified by multiple embodiments below.

The devices in the embodiments of the present application all adopt the ITO/HIL/HTL/QD/ETL/AL structure, and a certain heating treatment is performed after packaging. The advantages of the technical solutions of the present application are explained in detail by comparing the collocation of different functional layers in the device. In the following Examples, the service life test adopts a constant current method, and under the constant current of 50 mA/cm², the silicon photosystem is used to test the brightness change of the device. The 1000 nit LT95S service life of the device is extrapolated by empirical formula. This method is convenient for comparing the service lives of devices having different brightness levels, and has a wide range of applications in practical optoelectronic devices.

1000 nit LT95=(L_{Max}/1000)^{1.7}×LT95

The energy level test method of each material in Examples of the present application is as follows: after spin-coating of all functional layer materials to form films, the energy level test is carried out by an ultraviolet photoelectron spectroscopy (UPS) method.

Work function Φ=hv-E_{cutoff}, where hv is an energy of incident excitation photons, and E_{cutoff} is a cut-off position of excited secondary electrons;

Valence band top VB(HOMO): E_{HOMO}=E^{F-HOMO}+Φ, where E^{F-HOMO} is a difference between the HOMO(VB) of the material and the Fermi level, corresponding to a start edge of a first peak at a low binding energy end in a binding energy spectrum;

Bottom of conduction band (LOMO): E_{LOMO}=E_{HOMO}−E^{HOMO-LOMO}, where E^{HOMO-LOMO} is a band gap of the material, obtained from the ultraviolet absorption spectrum (UV-Vis).

### EXAMPLES 1 TO 11

In order to verify the influence of the hole injection barrier between the shell layer material of the quantum dot material and the hole transport material on the device performance, the present application conducted Examples 1 to 11, and compared the combinations of different HTLs and QDs to illustrate the effect of hole injection barrier on performance such as service life of the device.

Two kinds of quantum dots used in Examples 1 to 11 of the present application were as follows: blue QD1 having CdZnS as a shell (the core was CdZnSe, the intermediate shell layer was ZnSe, the shell thickness was 1.5 nm, and a valence band top energy level was 6.2 eV), a blue QD2 having ZnS as a shell (the core was CdZnSe, the intermediate shell was ZnSe, the ZnS shell thickness was 0.3 nm, and the valence band top energy level was 6.5 eV), and a blue QD3 having ZnSeS as a shell (the core was CdZnSe, the intermediate shell layer was ZnSe). The hole transport materials were P9 (E_{HOMO}: 5.1 eV), P15 (E_{HOMO}: 5.8 eV), the hole injection layer was PEDOT: PSS (E_{HOMO}: 5.1 eV), the electron transport layer was made of a Zinc oxide nanomaterial containing an amine/carboxyl ligand having a chain length of between 3 and 8 carbon atoms bound on the surface, and was prepared by amine/carboxyl ligand compound as the ligand and zinc oxide precursor as the precursor using the sol-gel method, which are specifically listed in Table 1 below:

TABLE 1

| | Blue | Hole | | Molar | | 1000 nit |
|---|---|---|---|---|---|---|
| Device | QD | transport | | ratio of | ΔE_{EML-HTL} | LT95 |
| number | shell | material | Ligand L | L to P | (eV) | (hr) |
| Example 1 | CdZnS (6.2 eV) | P15 (5.8 eV) | propylamine | 6:1 | 0.4 | 0.72 |
| Example 2 | CdZnS (6.2 eV) | P9 (5.1 eV) | propylamine | 6:1 | 1.1 | 1.26 |
| Example 3 | ZnS (6.5 eV) | P15 (5.8 eV) | propylamine | 6:1 | 0.7 | 6.29 |
| Example 4 | ZnSeS (6.3 eV) | P15 (5.8 eV) | propylamine | 6:1 | 0.5 | 6.26 |
| Example 5 | ZnS (6.5 eV) | P11 (5.5 eV) | propylamine | 6:1 | 1.0 | 11.82 |
| Example 6 | ZnS (6.5 eV) | P9 (5.1 eV) | propylamine | 6:1 | 1.4 | 35.2 |
| Example 7 | ZnS (6.5 eV) | P13 (4.9 eV) | propylamine | 6:1 | 1.6 | 31.2 |
| Example 8 | ZnS (6.5 eV) | P13 (4.9 eV) | None | / | 1.6 | 9.9 |
| Example 9 | ZnS (6.5 eV) | P13 (4.9 eV) | ethanolamine | 7:1 | 1.6 | 14.8 |
| Example 10 | ZnS (6.5 eV) | P13 (4.9 eV) | pentylamine | 4:1 | 1.6 | 30.2 |
| Example 11 | ZnS (6.5 eV) | P13 (4.9 eV) | octylamine | 2:1 | 1.6 | 16.6 |

From the test results in the above Table 1, it can be seen that for the same CdZnS (6.2 eV) shell quantum dots, as the HTL changes from P15 (5.8 eV) to P9 (5.1 eV), the Δ_{EML-HTL} barrier difference increases from 0.4 eV to 1.1 eV, the service life of the device is improved, and the 1000 nit LT95S service life increases from 0.72 to 1.26. In addition, for the same P15 (5.8 eV) material, as the quantum dot shell changes from CdZnS (6.2 eV) to ZnS (6.5 eV), the ΔE_{EML-HTL} barrier difference increases from 0.4 eV to 0.7 eV, and the service life of the device is significantly improved, that is, 1000nit LT95S service life increases from 0.72 to 6.29.

It can be seen that, either the HTL material or EML material is adjusted to increase the valence band top energy level difference ΔE_{EML-HTL} to higher than 0.5 eV, the device injection balance can be optimized, and the service life of the device can be enhanced. It indicates that the reduction of the hole injection efficiency by increasing the hole injection barrier can better balance the injection balance of holes and electrons in the light-emitting layer, and improve the luminous efficiency and luminous service life of the device. In addition, it can be known from Examples 7-11 that when the chain length of the amine/carboxyl ligand attached to the surface of the Zinc oxide is between 3 and 8 carbon atoms, the device performance is better promoted.

### EXAMPLES 12 TO 15

In order to verify the influence of the energy level barrier at the interface between the HIL and the HTL on the device performance, the present application conducted Examples 12 to 15, through the comparison of combination of different HTLs and HILs, to illustrate the impact of the ΔE_{HTL-HIL} hole injection barrier on the performances, such as the service life, of the devices.

Examples 12 to 13 of the present application adopted a blue quantum dot having ZnS as the shell (the core was CdZnSe, the intermediate shell layer was ZnSe, the shell thickness was 0.3 nm, and the valence band top energy level was 6.5 eV), and Examples 14 to 15 adopted a red quantum dot having ZnS as the shell (the core was CdZnSe, the intermediate shell layer was ZnSe, the shell thickness was 0.3 nm, and the valence band top energy level was 6.5 eV). The hole transport materials were P9 (E_{HOMO}: 5.5 eV), P11(E_{HOMO}: 5.5 eV), and P13 (E_{HOMO}: 4.9 eV) respectively. The hole injection layer adopted PEDOT: PSS (E_{HOMO}: 5.1 eV) and HIL2 (work function: 5.6 eV). The electron transport layer adopted Zinc oxide nanomaterial having a propylamine ligand attached on the surface thereof, and was prepared by according to the molar ratio of ligand compound (Ligand) and zinc oxide precursor (Precursor) of 6:1 through the sol-gel method, as shown in Table 2 below:

TABLE 2

| Device | | Hole transport | Hole injection | | |
|---|---|---|---|---|---|
| numbers | Blue QD shell | layer | layer | ΔE_{HTL-HIL} (eV) | LT95 (hr) |
| Example 12 | ZnS (6.5 eV) | P11 (5.5 eV) | PEDOT:PSS (5.1 eV) | 0.4 | 11.82 |
| Example 13 | ZnS (6.5 eV) | P13 (4.9 eV) | | −0.2 | 31.2 |
| Device | | Hole transport | | | |
| numbers | Red QD shell | layer | | ΔE_{HTL-HIL} (eV) | LT95 (hr) |
| Example 14 | ZnS (6.5 eV) | P9 (5.1 eV) | | 0.0 | 1094.78 |
| Example 15 | ZnS (6.5 eV) | P9 (5.1 eV) | HIL2 (5.6 eV) | −0.5 | 12221.49 |

Note:
When ΔE_{HTL-HIL} < 0.2 eV, under the existing HIL materials and experimental data, ΔE_{EML-HTL} is necessarily greater than 0.5 eV.

As shown in the test results in the above Table 2, it can be known, from the comparison of the blue quantum dot devices between Examples 12 and 13 and from the comparison of the red quantum dot devices of Examples 14 and 15, that when the hole injection energy level barrier between the HTL and the HIL was ΔE_{HTL-HIL}<−0.2 eV, the service life of the device of 1000 nit LT95S was improved compared to the Example in which ΔE_{HTL-HIL} was greater than or equal to −0.2 eV, which means that as the hole injection barrier increases from the anode to the HIL, the overall rate of hole injection in the QLED device is reduced, and the number of holes entering the QLED device is effectively controlled, which not only improves the carrier recombination efficiency, but also avoids charge accumulation at the interface of HTL and HIL caused by excessive injection, thereby increasing the luminescence service life of the device.

### EXAMPLES 16 TO 23

In order to verify the influence of the energy level barrier at the interface between the HIL and the HTL on the device performance, the present application conducted Examples 16 to 23, through the comparison of different HTLs and HILs, to illustrate the impact of the hole injection barrier |ΔE_{HTL-HIL}| on the performance of the device, such as driving voltage.

Examples 16 to 18 of the present application adopted a blue quantum dot having ZnS as the shell (the core was CdZnSe, the intermediate shell layer was ZnSe, the shell thickness was 0.3 nm, and the valence band top energy level was 6.5 eV), and Examples 19 to 23 adopted a red quantum dot having ZnS as the shell (the core was CdZnSe, the intermediate shell layer was ZnSe, the shell thickness was 0.3 nm, and the valence band top energy level was 6.5 eV). The hole transport materials were P9 (E_{HOMO}: 5.5 eV), P13 (E_{HOMO}: 4.9 eV), and TFB (E_{HOMO}: 5.4 eV), respectively. The hole injection layer adopted PEDOT: PSS (E_{HOMO}: 5.1 eV), HIL1 (work function: 5.4 eV), and HIL2 (work function: 5.6 eV). The electron transport layer adopted Zinc oxide nanomaterial having a propylamine ligand attached on the surface thereof, and was prepared by according to the molar ratio of ligand compound (Ligand) and zinc oxide precursor (Precursor) of 6:1 through the sol-gel method, as shown in Table 3 below:

TABLE 3

| | | Hole | | | Voltage |
|---|---|---|---|---|---|
| Device | Blue QD | transport | Hole injection layer | ΔE_{HTL-HIL} | increase |
| numbers | shell | material | material | (eV) | (V)@16 H |
| Example 16 | ZnS (6.5 eV) | TFB (5.4 eV) | PEDOT:PSS (5.1 eV) | 0.3 | 0.7 |
| Example 17 | ZnS (6.5 eV) | P9 (5.1 eV) | PEDOT:PSS (5.1 eV) | 0 | 0.25 |
| Example 18 | ZnS (6.5 eV) | P13 (4.9 eV) | PEDOT:PSS (5.1 eV) | −0.2 | 0.4 |
| | | Hole | | | Voltage |
| Device | Red QD | transport | Hole injection layer | ΔE_{HTL-HIL} | increase |
| numbers | shell | material | material | (eV) | (V)@20 H |
| Example 19 | ZnS (6.5 eV) | TFB (5.4 eV) | PEDOT:PSS (5.1 eV) | 0.3 | 1 |
| Example 20 | ZnS (6.5 eV) | P15 (5.8 eV) | PEDOT:PSS (5.1 eV) | 0.7 | 1.9 |
| Example 21 | ZnS (6.5 eV) | P15 (5.8 eV) | HIL2 (5.6 eV) | 0.2 | 0.3 |
| Example 22 | ZnS (6.5 eV) | TFB (5.4 eV) | HIL1-1 (5.4 eV) | 0 | −0.4 |
| Example 23 | ZnS (6.5 eV) | TFB (5.4 eV) | HIL1-2 (5.3 eV) | 0.1 | −0.4 |

From the test results in the above Table 3, it can be seen that when the hole injection energy level barrier |ΔE_{HTL-HIL}| between the HTL and the HIL is smaller than or equal to 0.2 eV, compared with the Examples having the |ΔE_{HTL-HIL}| greater than 0.2, only a small amount of charge accumulated at the hole transport side of the device. Under the constant current operation of the device for a long time, the driving voltage increase of the device was significantly reduced, and the service life of the device of 1000nit LT95S was improved. Moreover, when the potential barrier difference between the HIL and the HTL was very small, there was almost no charge accumulation at the interface and no aging on the opposite side, the hole injection capability of the device was stable, and the service life of the device was also improved, which means that the lowering the energy level barrier of hole injection was beneficial to the effective injection of holes from HIL to HTL, thereby eliminating the potential barrier and interface charge, reducing the overall resistance of the device, and improving the service life of the device.

### EXAMPLES 24 TO 28

In order to verify the influence of the hole injection layer on the device performance, the present application conducted the following examples. Examples 24 to 26 adopted the red quantum dot having ZnS as the shell (the core was CdZnSe, the intermediate shell layer was ZnSe, and the valence band top energy level was 6.5 eV). Examples 27-28 adopted the red quantum dot having ZnS as the shell (the core was CdZnSe, the intermediate shell was ZnSe, and the valence band top energy level was 6.5 eV). The electron transport layer adopted Zinc oxide nanomaterial having a propylamine ligand attached on the surface thereof, and was prepared by according to the molar ratio of ligand compound (Ligand) and zinc oxide precursor (Precursor) of 6:1 through the sol-gel method, as shown in Table 4 below:

TABLE 4

| | | | Mobility | Hole | | |
|---|---|---|---|---|---|---|
| | Red | Hole | of hole | injection | | Voltage |
| Device | QD | transport | transport | layer | T95 | increase |
| numbers | shell | material | material | material | (hr) | (V)@40 H |
| Example 24 | ZnS (6.5 eV) | TFB (5.4 eV) | 1.00E−03 | PEDOT:PSS (5.1 eV) | 2000 | 1.5 |
| Example 25 | ZnS (6.5 eV) | TFB (5.4 eV) | 1.00E−03 | None | 162.5 | −0.3 |
| Example 26 | ZnS (6.5 eV) | P11 (5.5 eV) | 1.30E−03 | None | 1436 | −0.15 |

| | | | Mobility | Hole | | Voltage |
|---|---|---|---|---|---|---|
| | Red | Hole | of hole | injection | | increase (V) |
| Device | QD | transport | transport | layer | T95 | (Lₘₐₓ to |
| numbers | shell | material | material | material | (hr) | L95) |
| Example 27 | ZnS (6.5 eV) | TFB (5.4 eV) | 1.00E−03 | MoO₃ | 2357 | −0.2 |
| Example 28 | ZnS (6.5 eV) | TFB (5.4 eV) | 1.00E−03 | PEDOT:PSS (5.1 eV) | 2000 | 0.8 |

From the test results in the above Table 4, it can be seen that when the HIL layer was removed from the device, the charge accumulation between the hole injection layer and the hole transport layer and the influence of acidic PEDOT on the device disappeared. Under the constant current operation of the device for a long time, the driving voltage of the device was almost unchanged, even as the charge filled the defects in the device, the device driving voltage tended to decrease. Using the P11 material with higher mobility, after preparing the HIL-free device, the driving voltage of the device dropped more obviously under the constant current operation for a long time, which indicates that when the selected HTL mobility is higher than 1×10⁻³ cm²/Vs, better performance in suppressing the voltage rise of the device can be achieved.

In addition, when the inorganic metal oxide MoO₃ was used to replace the organic PEDOT: PSS as the hole injection layer material, the damage of the MoO₃ hole injection material was effectively suppressed, so that the device adopting such material, compared with the device adopting the organic hole injection layer material, had significant reduction in the voltage rise during the working process, as well as effectively improved measured time of the service life of the device.

The above are only optional embodiments of the present application, and are not intended to limit the present application. Various modifications and variations of the present application are possible for those skilled in the art. Any modification, equivalent replacement, improvement, and the like made within the spirit and principle of the present application shall be included within the scope of the claims of the present application.

1. An optoelectronic device, comprising:
an anode,
a hole transport layer disposed on the anode,
a quantum dot light-emitting layer disposed on the hole transport layer,
an electron transport layer disposed on the quantum dot light-emitting layer, and
a cathode disposed on the electron transport layer;
wherein
the quantum dot light-emitting layer comprises a quantum dot material in a core-shell structure; a valence band top energy level difference between an shell layer material of the quantum dot material and a hole transport material in the hole transport layer is greater than or equal to 0.5 eV; and
the electron transport layer comprises a zinc oxide nanomaterial, and a surface of the zinc oxide nanomaterial is bound with an amine/carboxyl ligand having a chain length of between 3 and 8 carbon atoms.

2. The optoelectronic device according to claim 1, wherein the valence band top energy level difference between the shell layer material of the quantum dot material and the hole transport material is between 0.5 eV and 0.7 eV.

3. The optoelectronic device according to claim 1, wherein the valence band top energy level difference between the shell layer material of the quantum dot material and the hole transport material is between 0.7 eV and 1.0 eV.

4. The optoelectronic device according to claim 1, wherein the valence band top energy level difference between the shell layer material of the quantum dot material and the hole transport material is between 1.0 eV and 1.4 eV.

5. The optoelectronic device according to claim 1, wherein the valence band top energy level difference between the shell layer material of the quantum dot material and the hole transport material is between 1.4 eV and 1.7 eV.

6. The optoelectronic device according to claim 1, wherein the zinc oxide nanomaterial is prepared by a sol-gel method according to a ratio of an amine/carboxyl ligand compound to a zinc oxide precursor of (1 to 10):1.

7. The optoelectronic device according to claim 6, wherein the amine/carboxyl ligand compound is at least one selected from the group consisting of propionic acid, propylamine, butyric acid, butylamine, hexanoic acid, hexylamine, pentylamine, and octylamine.

8. The optoelectronic device according to claim 6, wherein the zinc oxide precursor is at least one selected from the group consisting of zinc acetate, zinc nitrate, zinc sulfate, and zinc chloride.

9. The optoelectronic device according to claim 7, wherein
when the chain length of the amine/carboxyl ligand compound is between 3 and 4 carbon atoms, the zinc oxide nanomaterial is prepared according to the ratio of the amine/carboxyl ligand compound to the zinc oxide precursor of (4 to 10):1; and
when the chain length of the amine/carboxyl ligand compound is between 5 and 7 carbon atoms, the molar ratio of the amine/carboxyl ligand compound to the zinc oxide precursor is (1 to 5):1, to prepare the zinc oxide nanomaterial.

10. The optoelectronic device according to claim 1, wherein the hole transport material is at least one selected from the group consisting of TFB, poly-TPD, P11, P09, P13, P15, and P12.

11. The optoelectronic device of claim 1, wherein the hole transport material has a mobility of higher than 1×10⁻⁴ cm²/Vs.

12. The optoelectronic device according to claim 10, wherein
the optoelectronic device further comprises a hole injection layer;
the hole injection layer is disposed between the anode layer and the hole transport layer; and
a difference between a valence band top energy level of the hole transport material and a work function of a hole injection material of the hole injection layer is smaller than -0.2 eV, or an absolute value of the difference between the valence band top energy level of the hole transport material and the work function of the hole injection material of the hole injection layer is smaller than or equal to 0.2 eV.

13. The optoelectronic device according to claim 12, wherein when the difference between the valence band top energy level of the hole transport material and the work function of the hole injection material is smaller than −0.2 eV, an absolute value of the work function of the hole injection material is between 5.4 eV and 5.8 eV; and
when the absolute value of the difference between the valence band top energy level of the hole transport material and the work function of the hole injection material is smaller than or equal to 0.2 eV, the absolute value of the work function of the hole injection material is between 5.3 eV and 5.6 eV.

14. The optoelectronic device according to claim 13, wherein the hole injection material is selected from at least one metal nanomaterial selected from the group consisting of tungsten oxide, molybdenum oxide, vanadium oxide, nickel oxide, and copper oxide.

15. The optoelectronic device according to claim 1, wherein the quantum dot material in the core-shell structure further comprises: an core, and an intermediate shell layer disposed between the core and the shell layer.

16. The optoelectronic device according to claim 15, wherein the shell layer of the quantum dot material comprises an alloy material formed by at least one or at least two of CdS, ZnSe, ZnTe, ZnS, ZnSeS, CdZnS, and PbS.

17. The optoelectronic device according to claim 15, wherein the core of the quantum dot material comprises at least one of CdSe, CdZnSe, CdZnS, CdSeS, CdZnSeS, InP, InGaP, GaN, GaP, ZnSe, ZnTe, and ZnTeSe.

18. The optoelectronic device according to claim 15, wherein a material of the intermediate shell material is at least one selected from CdZnSe, ZnSe, CdZnS, CdZnSeS, CdS, and CdSeS.

19. The optoelectronic device according to claim 8, wherein
when the chain length of the amine/carboxyl ligand compound is between 3 and 4 carbon atoms, the zinc oxide nanomaterial is prepared according to the ratio of the amine/carboxyl ligand compound to the zinc oxide precursor of (4 to 10):1; and
when the chain length of the amine/carboxyl ligand compound is between 5 and 7 carbon atoms, the molar ratio of the amine/carboxyl ligand compound to the zinc oxide precursor is (1 to 5):1, to prepare the zinc oxide nanomaterial.

20. The optoelectronic device according to claim 5, wherein the zinc oxide nanomaterial is prepared by a sol-gel method according to a ratio of an amine/carboxyl ligand compound to a zinc oxide precursor of (1 to 10):1.
